(19) United States
(12) Patent Application Publication
(10) Pub. No.: US 2011/0050214 A1
(43) Pub. Date: Mar. 3, 2011

(54) SYSTEM AND METHOD FOR MEASURING MAGNETIC FIELD STRENGTH USING A MECHANICAL RESONATOR

(75) Inventors: Behraad Bahreyni, Winnipeg (CA); Cyrus Shafai, Winnipeg (CA)

(73) Assignee: THE UNIVERSITY OF MANITOBA, WINNIPEG, MB (CA)

(21) Appl. No.: 12/300,187

(22) PCT Filed: Oct. 31, 2006
(86) PCT No.: PCT/CA2006/001780

§ 371 Date: Jul. 5, 2010

Related U.S. Application Data
(60) Provisional application No. 60/799,005, filed on May 10, 2006.

(51) Int. Cl. G01R 33/02; H03K 3/00

(52) U.S. Cl. 324/244; 327/291

(57) ABSTRACT

Methods and apparatus for measuring magnetic field are provided. A resonator having a resonant frequency is that varies as a function of magnetic field is driven with a drive signal, and produces an output that is converted to electrical form. This output is then processed to isolate interference components due to the drive signal and to produce a sense signal. The sense signal is the processed to produce the drive signal. The sense signal is also processed to produce an output representative of the magnetic field.

### RELATED APPLICATION

This application claims the benefit of prior U.S. provisional application No. 60/799,005 filed May 10, 2006.

### FIELD OF THE INVENTION

The invention relates to methods and systems for measuring magnetic field strength.

### BACKGROUND OF THE INVENTION

Micromachining is becoming a mature technology and many of the micromachining projects are in the process of commercialization. As is the case for microelectronic technology, if fabrication, or at least prototyping, of a sensor is possible using a standard process, considerable savings can result in terms of overall cost and development time for a device. See for example M. N. Horenstein and P. R. Stone, Journal of Electrostatics, vol. 51-52, pp. 515-521, May 2001.

An example of the analytic modeling and Finite Element Simulations of a resonant micromachined magnetic field sensor is described in Bahreyni, Behraad; Shafai, Cyrus, “Analytic Modeling and FEM Simulation of a Resonant Micromachined Magnetic Field Sensor”, Canadian Conference of Electrical & Computer Engineering, May, 2004 hereby incorporated by reference in its entirety. The resonant frequency of the sensor changes in response to the magnitude and direction of the present magnetic field. The output of the micromachined magnetic field sensor is input to a frequency measurement device such as a spectrum analyzer. An AC input voltage drives the arrangement, and the frequency of the AC voltage is swept across a range of interest. The overall frequency response is examined to determine the peak, and that corresponds to the resonant frequency. The resonant frequency, once determined, is used to determine the magnetic field using knowledge of the relationship between the resonant frequency and magnetic field.

### SUMMARY OF THE INVENTION

According to one broad aspect, the invention provides an apparatus for measuring magnetic field comprising: a mechanical resonator having a resonator output and having an input for receiving a drive signal; signal conversion and amplification circuitry for converting the resonator output of the mechanical resonator into a voltage output; and a sense signal filtering circuit to isolate a sense signal from an interfering feedthrough signal.

In some embodiments, the sense signal filtering circuit comprises at least one of: a notch filter having a notch at the expected resonant frequency divided by two; one or more bandpass filters to isolate the sense signal from the interference signal; and one or more additional high-Q bandpass filters to remove beating components.

In some embodiments, the apparatus connected to form an oscillator loop with a feedback signal processing circuit that processes the sense signal to produce the drive signal; wherein the sense signal has a frequency shift representative of a magnetic field within which the apparatus is situated.

According to another broad aspect, the invention provides an apparatus for measuring magnetic field comprising: a mechanical resonator that undergoes mechanical motion and has an input for receiving a drive signal, the mechanical resonator having a resonant frequency that changes as a function of magnetic field; a motion detector that detects the mechanical motion of the mechanical resonator; and a sense signal filtering circuit for filtering a signal representative of the mechanical motion of the mechanical resonator to isolate a sense signal from interference due to the drive signal.

In some embodiments, the apparatus further comprises: signal conversion and amplification circuitry for converting an output of the motion detector into a voltage output as the signal representative of the mechanical motion of the mechanical resonator.

In some embodiments, the sense signal filtering circuit comprises at least one of: a notch filter having a notch at an expected resonant frequency divided by two; one or more bandpass filters to isolate the sense signal from the interference due to the drive signal; and one or more additional high-Q bandpass filters to remove beating components.

In some embodiments, the apparatus further comprises: a feedback signal processing circuit that processes the sense signal to produce the drive signal; wherein the sense signal has a frequency shift representative of a magnetic field within which the apparatus is situated.

In some embodiments, the feedback signal processing circuit comprises: a constant amplitude circuit to make the sense signal have substantially constant amplitude; a divide by 2 circuit; a phase adjustment circuit.

In some embodiments, the apparatus further comprises: an output processing circuit that processes the sense signal to produce an output representative of the magnetic field within which the apparatus is situated.

In some embodiments, the output processing circuit comprises: a frequency dependent phase shifting circuit that produces a phase shifted output; and a circuit that determines a phase shift introduced by the phase shifting circuit.

In some embodiments, the circuit that determines a phase shift introduced by the phase shifting circuit comprises: a phase detector.

In some embodiments, the apparatus further comprises a phase difference to voltage converter, that produces a voltage that represents a value for the magnetic field.

In some embodiments, the apparatus further comprises a downconverter circuit that downconverts a frequency of the sense signal.

In some embodiments, the phase shifting circuit comprises an all pass filter.

In some embodiments, the mechanical resonator comprises a resonant micromachined magnetic field sensor.

In some embodiments, the mechanical resonator is driven by means of electrostatic, optical, thermal, piezoelectric, piezoresistive.

In some embodiments, the motion detector comprises one of an electrostatic motion detector, optical motion detector, thermal motion detector, piezoelectric motion detector, and piezoresistive motion detector.

According to another broad aspect, the invention provides a method comprising: placing a mechanical resonator having a resonator output and having an input for receiving a drive signal in an area for which a magnetic field measurement is to be determined; converting and amplifying the resonator output into an electrical signal output; and filtering the electrical signal output to isolate a sense signal from an interfering feedthrough signal.

In some embodiments, the method further comprises: feeding a version of the sense signal back as the drive signal to form a closed loop.

In some embodiments, the method further comprises: performing feedback signal processing upon the sense signal to produce the drive signal.

In some embodiments, the method further comprises: processing the sense signal to produce an output representative of the magnetic field.

According to another broad aspect, the invention provides a resonator arrangement comprising: a mechanical resonator having a drive signal and a resonator output; a drive signal generation circuit that generates the drive signal for the mechanical resonator from the resonator output.

In some embodiments, the mechanical resonator is a MEMS resonator.

In some embodiments, the drive signal generation circuit comprises: signal conversion and amplification circuitry for converting the resonator output of the mechanical resonator into a voltage output; and a sense signal filtering circuit to isolate a sense signal from an interfering feedthrough signal.

In some embodiments, the sense signal filtering circuit comprises at least one of: a notch filter having a notch at the expected resonant frequency divided by two; one or more bandpass filters to isolate the sense signal from the interference signal; and one or more additional high-Q bandpass filters to remove beating components.

In some embodiments, the drive signal generation circuit comprises: a motion detector that detects the mechanical motion of the mechanical resonator; and a sense signal filtering circuit for filtering a signal representative of the mechanical motion of the mechanical resonator to isolate a sense signal from interference due to the drive signal.

In some embodiments, the resonator arrangement further comprises: signal conversion and amplification circuitry for converting an output of the motion detector into a voltage output as the signal representative of the mechanical motion of the mechanical resonator.

In some embodiments, the apparatus drive signal generation circuit further comprises: a feedback signal processing circuit that processes the sense signal to produce the drive signal.

In some embodiments, the feedback signal processing circuit comprises: a constant amplitude circuit to make the sense signal have substantially constant amplitude; a divide by 2 circuit; a phase adjustment circuit.

### BRIEF DESCRIPTION OF THE DRAWINGS

Embodiments of the invention will now be described with reference to the attached drawings in which:

FIG. 1A is a block diagram of an apparatus that can be used for measuring magnetic fields;

FIG. 1B is a block diagram of an apparatus for measuring magnetic fields;

FIG. 2 is a circuit diagram used to drive a resonator according to an embodiment of the invention;

FIG. 3 is a block diagram of an example of an oscillator network according to an embodiment of the invention;

FIG. 4 is a block diagram of an example of the oscillator network of FIG. 3 along with output processing components; and

FIG. 5 is a schematic of an example micromachined magnetic field sensor employed as a electrostatic resonator according to an embodiment of the invention.

### DETAILED DESCRIPTION

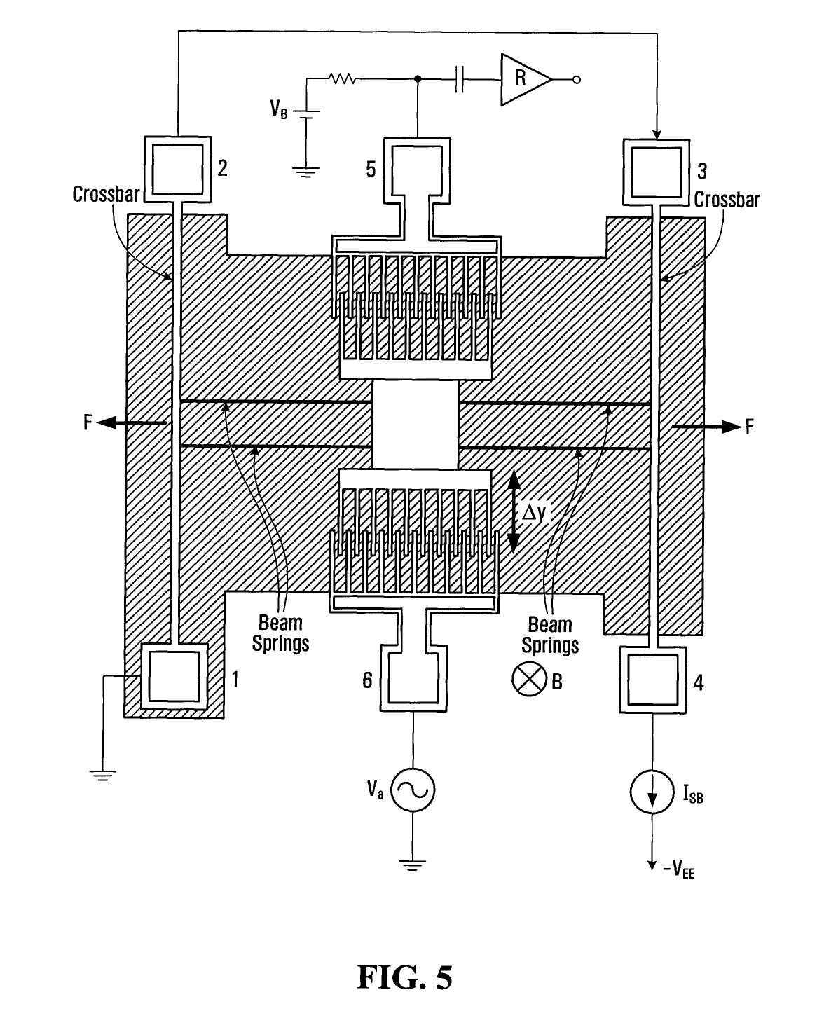

Various methods of employing a mechanical resonator using electrostatic, piezoelectric, piezoresistive, thermal, or other actuation mechanism as a magnetic field sensor will be described. Particular implementations employ micromachined magnetic field sensors described with reference to FIG. 5 in detail below. However, more generally any mechanical structure that has a resonant frequency that varies as a function of an axial stress can be employed, for example due to an applied magnetic field.

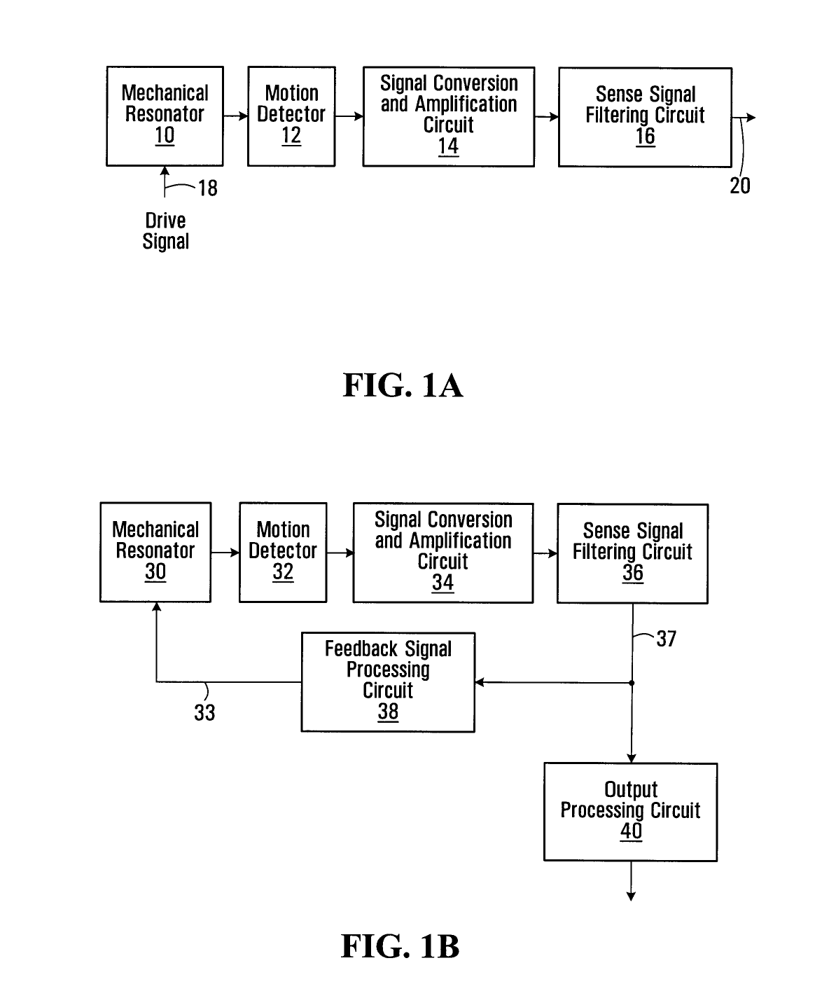

FIG. 1A is a block diagram of an apparatus that can be used for measuring magnetic fields. The system comprises a mechanical resonator 10 that has a resonant frequency that varies as a function of magnetic field in which the apparatus is located. The mechanical resonator 10 undergoes mechanical motion that is detected by a motion detector 12. The mechanical resonator 10 receives a drive signal 18. The motion detector produces a signal representative of the mechanical motion of the mechanical resonator. This is followed by an optional signal conversion and amplification circuit 14 that performs any necessary signal conversion from the form output by the motion detector 12 into a form suitable for electronic processing. This might for example simply consist of a current to voltage conversion and amplification. The output of the signal conversion and amplification circuit 14 is fed to a sense signal filtering circuit 16. This output is also representative of the mechanical motion of the mechanical resonator. The sense signal filtering circuit 16 performs filtering on the signal to isolate a sense signal 20 from interference due to the drive signal 18. The sense signal can be analyzed to determine the resonant frequency of the mechanical resonator assuming an appropriate drive signal, for example any AC drive signal that is swept across a range of frequencies.

FIG. 1B is a block diagram of an apparatus for measuring magnetic fields. The system comprises a mechanical resonator 30 that has a resonant frequency that varies as a function of magnetic field in which the apparatus is located. The mechanical resonator 30 undergoes mechanical motion that is detected by a motion detector 32. The mechanical resonator receives a drive signal 33. The motion detector 32 produces a signal representative of the mechanical motion of the mechanical resonator 30. This is followed by an optional signal conversion and amplification circuit 34 that performs any necessary signal conversion from the form output by the motion detector 32 into a form suitable for electronic processing. This might for example simply consist of a current to voltage conversion and amplification. The output of the signal conversion and amplification circuit 34 is fed to a sense signal filtering circuit 36. This output is also representative of the mechanical motion of the mechanical resonator 30. The sense signal filtering circuit 36 performs filtering on the signal to isolate a sense signal 37 from interference due to the drive signal 33. In the closed loop configuration of FIG. 1B, the sense signal 37 is representative of the resonant frequency of the mechanical resonator as described later.

The sense signal 37 output by the sense signal filtering circuit 36 is then fed through a feedback signal processing circuit 38 and back into the mechanical resonator 30 as the drive signal 33 to form an oscillator loop. The output of the sense signal filtering circuit 36 is representative of the resonant frequency of mechanical resonator, and this in turn is representative of the magnetic field. In some embodiments, additional circuitry is provided to convert that sense signal into a more representative form. FIG. 1 shows an output processing circuit 40 that can be used to this effect.

In the description below, various detailed examples of the functionality that might be included in the various circuits of FIGS. 1A and 1B will be described. However, it is to be understood that the embodiments of FIGS. 1A and 1B are not to be limited to those specific examples.

The mechanical resonator is driven by means of an appropriate drive signal. Examples of the form this signal might take include electrostatic, optical, thermal, piezoelectric, piezoresistive, but others are possible.

The motion detector is any device capable of measuring the mechanical motion of the mechanical resonator. Examples include an electrostatic motion detector, optical motion detector, thermal motion detector, piezoelectric motion detector, and piezoresistive motion detector, but others are possible. The mechanical resonator may provide a suitable output on its own without a separate motion detector. The motion detector and mechanical resonator may be separate devices or an integrated device.

Driving the Resonator with No Bias

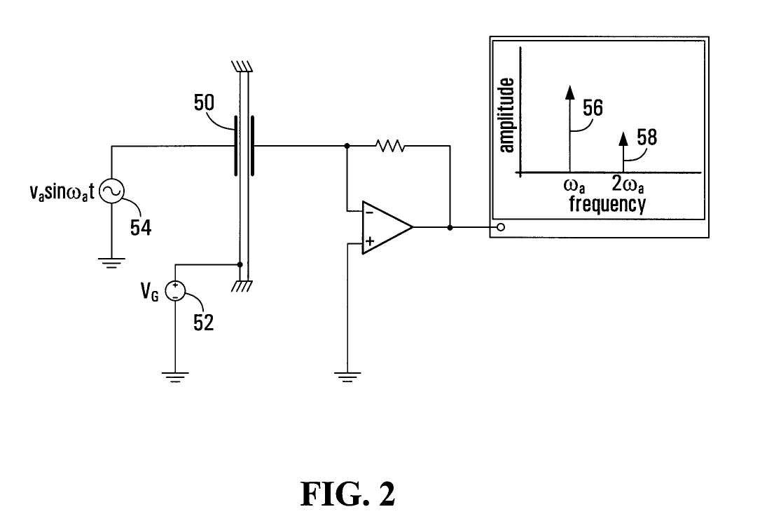

When driving an electrostatic or thermal resonator, a DC bias voltage can be used in order to bring down the level of the input AC voltages. An example of this is shown in FIG. 2 where an electrostatic resonator 50 is shown with a bias voltage V_{G} 52, and an input AC voltage 54 having an input frequency ωₐ. In practice, there is also a very large feedthrough/interference signal at the drive signal frequency which makes accurate electrical measurements (amplitude or phase) of the sense signal very difficult. This is shown in FIG. 2, where an example of the spectrum of the output is shown. The spectrum includes a component 56 at ωₐ. This is the drive frequency (ωₐ) given by the driving circuit 54. There is a second component at frequency 2ωₐ (twice the frequency of ωₐ), and this represents the motion of resonator 50, due to the drive frequency ωₐ. In the case of an electrostatically driven resonator embodiment of the sensor, the spike at frequency ωₐ is the electrical drive signal 54 which acts as an interference signal to the measurement and can be removed by subsequent filtering circuitry, and the spike at frequency 2wa is the signal due to the speed of oscillatory motion of the resonator itself and is indeed a measure of the oscillatory motion of the resonator itself.

If V_{G} is set to 0V for the system shown in FIG. 2, the output current should theoretically have a single component representative of the motion of the resonator at the second harmonic of the drive signal for electrostatic and thermally actuated resonators because of the quadratic relationship between the drive voltage and electrostatic or thermal force. Interference and feedthrough signals may still pose problems in taking accurate measurements. However, since the output signal of the device is at twice the frequency of the interfering signals, it is possible to recover the sense signal with proper filtering of the output signal. If the non-linearities of the electronics are kept to a minimum, the signal at the second harmonic will be entirely from the resonator operation.

### Using a Notch Filter

If bandpass or highpass filtering alone is to be employed to separate the sense signal from the interference signal, the small separation of the interference signal and the sense signal in the frequency domain and the needed amount of attenuation may require high order filters to extract the sensing signal. For example, if it is intended to attenuate the interference signal by a factor of about 5×10³ or 74 dB, a highpass filter with a minimum of 12 poles may be needed. Designing and implementing such a filter is not a straightforward process, and requires careful attention to the practical limits of the devices, their tolerances, and matching of components between the cascaded stages.

Instead of relying on achievable attenuation from poles, in some embodiments the interference signal is dealt with by placing the zeros of the transfer function of a filter at the frequency of the interference. Such a filter is often referred to as a notch filter. The filter's quality factor may be set to maximize the attenuation of the interfering signals. One or more bandpass filters at the frequency of the second harmonic may be used in additional to the notch filter to attenuate the interfering signals further and amplify the main signal. In some implementations, both of the filters are realized with switched capacitor filters.

### Removing Beating

The desired sense signal can be recovered by using a filter block consisting of a notch filter and bandpass filter as described above. However, beating between the output signal from the sensor and interfering signals from various sources (e.g., computer monitors and digital measurement equipment) may cause considerable variation in amplitude of the filter block output. Beating occurs when adding two sinusoidal signals whose frequencies are close to each other. In practice, neither the amplitude nor the frequency of the interfering signals is stable, which makes accurate measurements of the desired signal more difficult.

In some embodiments, additional high-Q bandpass filters are employed to shrink the bandwidth around the desired signal frequency and reject the signals outside of this band. However, tuning of these filters can be troublesome due to their narrow frequency response. In some embodiments, switched capacitor filters are used to greatly simplify the design flow, especially since the clock signal of the first filter block can be used for these high-Q filters, assuming it is also implemented with switched capacitor technology.

### Dividing the Frequency by Two

The sense signal can be recovered using the setup described above. In some embodiments, to alleviate the need for a signal source, the resonator is used in an oscillator loop. The implementation of FIG. 1B takes this approach. The problem of the feedthrough signal in the oscillator design case can still be circumvented with the same circuitry described above. However, in some designs the electrostatic resonator has to be driven at half the resonant frequency of the device in this setup. Therefore, in such instances the frequency of the processed signal has to be divided by two.

Driving the Resonator with a Constant Amplitude

In some embodiments, since the magnetic field data is extracted from the frequency shifts of the signal from the sensor, the amplitude information is discarded. This can be done by processing the sinusoidal signal with an analog comparator to convert the sinusoidal wave into a square wave. Counting over a window produces a moving average representative of the sense frequency. Dividing the signal frequency by two can then be simply done with a T-flipflop. To minimize the spurious signals at the output of the oscillator, the output of the frequency divider is then converted back to sinusoidal, for example with a 4th order lowpass filter which attenuates the 3rd harmonic of the output of the frequency divider by about 40 dB. Using this configuration, the amplitude of the excitation signal is completely defined and set by the user and does not rely on the properties of the linear and nonlinear elements in the loop. A phase adjustment circuit between the lowpass filter and the resonator can also be used to assure excitation of the resonator at the correct frequency and phase.

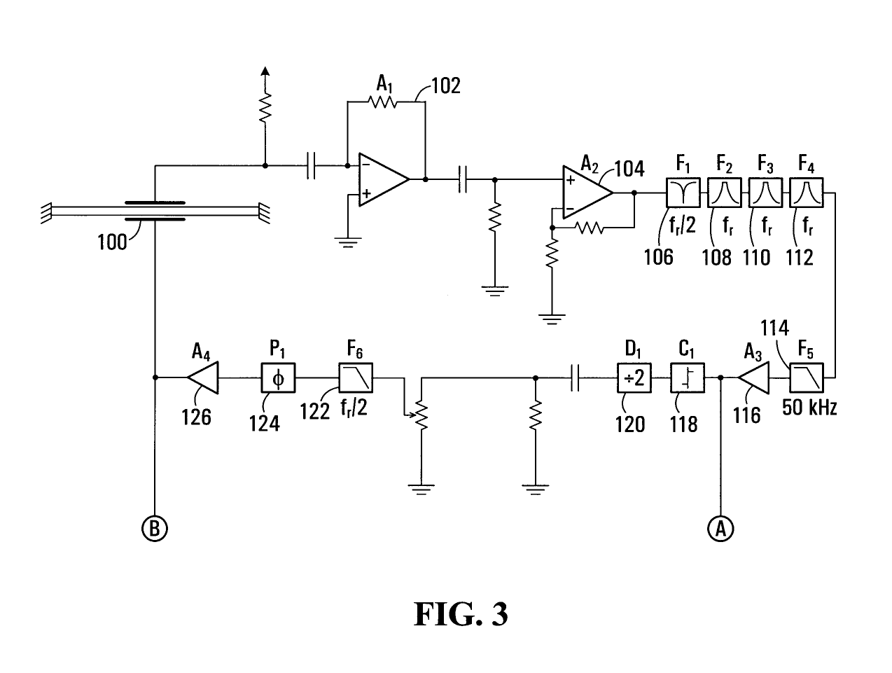

FIG. 3 is a block diagram of an example of the oscillator network, this being a very specific example of the implementation of the mechanical resonator, motion detector, signal conversion and amplification circuit, sense signal filtering circuit and signal processing circuit of FIG. 1B. This configuration improves the quality of the oscillator as a whole and greatly reduces phase-noise and jitter. This configuration includes all of the components discussed above, but not every implementation need include all of the components.

Shown is a mechanical resonator connected to a motion detector comprising a first amplifier element 102, and a second amplifier element 104. The output of the second amplifier element 104 is connected to the input of a notch filter 106 having frequency response F₁ which includes a notch at frequency fᵣ/2, where fᵣ/2 is a nominal resonant frequency of the mechanical resonator 100. The notch frequency is set to match the frequency of the drive signal, thereby allowing an efficient elimination of most of the interference due to the drive signal. The output of the notch filter 106 is input to filters 108,110,112 connected together in sequence which are bandpass filters having frequency responses F₂, F₃, F₄ respectively that have passbands centred at the frequency fᵣ of the second harmonic. These are provided in addition to the notch filter 106 to attenuate the interfering signals further and amplify the main signal. In some implementations, both of the filters are realized with switched capacitor filters. In the example of FIG. 3, three bandpass filters (108, 110, and 112) are provided to remove beating. Less or more such filters can be used as needed in a practical implementation.

The output of filter 112 is connected to the input of a lowpass filter 114 has frequency response F₅ which is a lowpass filter having a cutoff frequency of 60 kHz in the particular example illustrated. This filter 114 is used to provide extra filtering to remove high frequency noise from the signal and the filters 108, 110, and 112 are used to remove the beating.

The output of the lowpass filter 114 is connected to an amplifier 116. The output of amplifier 116 is connected to the input of a comparator 118. The comparator output effectively produces a moving average of the twice the resonant frequency. Elements 116,118 function to remove the amplitude information from the sense signal, and give a digital indication of the resonator frequency. The output of the comparator 118 is divided by two with frequency divider circuit 120 to produce a drive signal near the resonant frequency of the mechanical resonator 100.

To reduce the spurious signals at the output of the oscillator, the output of the frequency divider is then converted back to sinusoidal, for example with a lowpass filter 122 having frequency response F₂ which attenuates the 3rd harmonic of the output of the frequency divider by about 40 dB. Using this configuration, the amplitude of the excitation signal is completely defined and set by the user and does not rely on the properties of the linear and nonlinear elements in the loop. A phase adjustment circuit 124 is provided between the lowpass filter 122 and the resonator 100 to assure excitation of the resonator at the correct frequency and phase. Element P1 124 may for example be implemented using an “all-pass filter”, which is used to adjust the phase of the signal coming from filter 122, so that it is in phase with the motion of the resonator 100. Element A4 126 represents the gain for the all pass filter P1. This is shown as a separate block as this amplification can be inherent to the filter P1, and/or be from an additional amplifier.

### Frequency Shift Measurement

Additional signal processing of the sense signal can be performed outside the loop to extract the magnetic field measurement. In some embodiments, this can be done by applying a frequency dependent phase-shift to the sense signal to convert the information embedded in the frequency of the signal to a phase difference between the sense signal and its delayed version. This can potentially improve the accuracy of measurements by converting small frequency shifts to relatively large phase differences. If the amplitude of the signal is controlled, the shifts in the resonant frequency of the structure are instantaneously converted to phase differences and can be measured. Therefore, sensitivity and bandwidth of measurements are both enhanced by using this technique.

The next step is to measure the phase difference in order to extract information about the amount of frequency shift. This can be done by using a phase detector which compares the relative phase of the signals at its inputs. As an example, the original signal and its phase-shifted (i.e., delayed) version can be converted to square waves by use of comparators. The phase difference between these square waves can then be measured with different digital phase detectors, such as an XOR gate. The output of the phase detector is then lowpass filtered to yield a DC voltage which is proportional to the phase difference between the input signals, and therefore, the amount of frequency shift in the original signal.

### Use of Allpass Filters

To avoid the resulting complexities of using passive phase shift networks, in some embodiments an allpass (or delay) filter is used to implement the phase shift. Allpass filters do not modify the amplitude of the signal through them but will cause a predetermined phase shift at the designed frequency. This is done by properly choosing the location of poles and zeros of a given transfer functions. More specifically, the zeros and poles have the same frequency (to produce a flat amplitude response) but the zeros are placed in the right-half portion of the s-plane (to increase the phase difference between high and low frequencies). If allpass networks of orders larger than one are used, it is possible to independently control the frequency and phase performance (i.e., Q) of the circuit.

The phases of the delayed signal and the signal that was not delayed are compared with the phase detector block which produces an output proportional to the phase difference. This output is representative of the magnetic field measurement.

### Down Conversion of Frequency

If the phase difference detection is to be done at the signal frequency, very high-Q allpass filters may be required. For example, if it is desired to have a 45° phase shift for a 1 Hz shift at the signal frequency of 40 kHz, a 2nd order allpass filter with a Q of about 6000 is needed, which is obviously difficult to realize. On the other hand, high-Q filters are generally prone to instability. Furthermore, tuning of high-Q filters is not easy because of their narrow bandwidth. To overcome these issues, in some embodiments a downconverter is used to bring down the frequency of the sense signal before feeding it to the delay circuitry. This reduction in signal frequency, which is essentially the same as removing the frequency offset that does not convey information, allows for performing sensitive phase difference measurements with relatively low-Q allpass filters. Additionally, if the difference between the downconverting signal and the sensor signal is kept constant, a stable and tuned circuit can be designed to produce the delay at the difference frequency, which greatly improves the versatility of the sensing electronics.

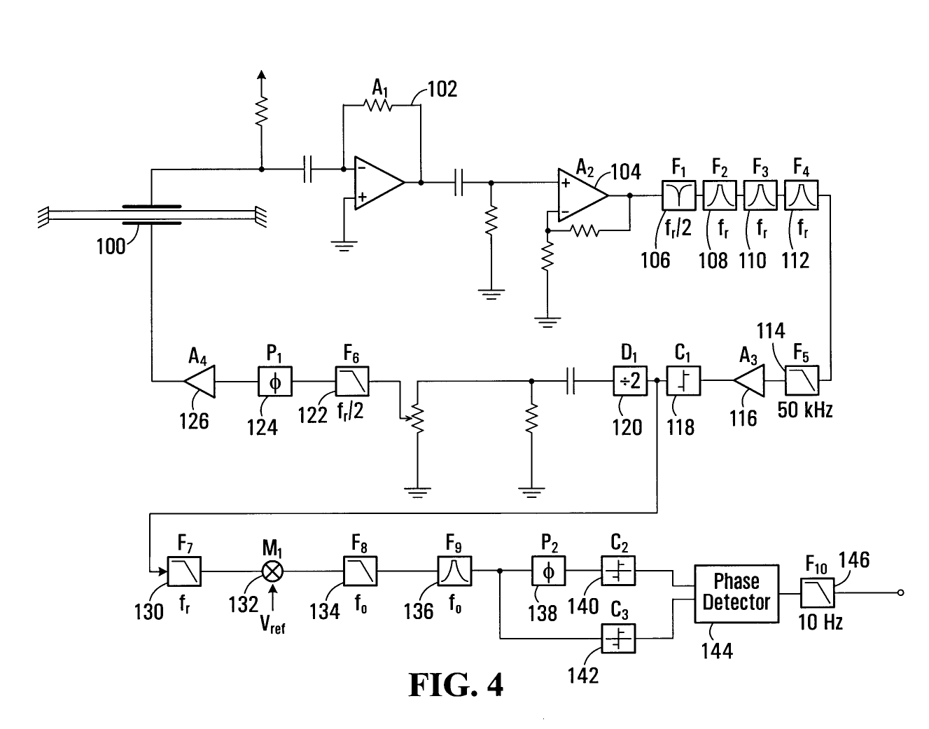

An example of a circuit including all of the output processing components described above is shown in FIG. 4, this circuit including the same components as described above with reference to FIG. 3 plus additional components for realizing a specific implementation of the output processing circuit of FIG. 1. More generally, a particular implementation may include no output processing, or an arbitrary subset of the output processing components discussed above.

The output processing components include a lowpass filter 130 having frequency response F₇ that may be implemented having a cutoff frequency fᵣ that is the same as that of filters 108,110,112 for convenience, but other cutoff frequencies can be employed. The output of filter 130 is passed to downconverter 132 that is controlled by a reference voltage V_{ref} which serves to produce a sense signal at a lower frequency. The output of downconverter 132 is subject to further filtering in filters 134,136 having frequency responses F₈, F₉ respectively to isolate the relevant component of the output of the downconverter 132. Filter 134 is a lowpass filter having cutoff frequency f₀. Filter 136 is a bandpass filter having passband centre frequency. The specific frequency f₀ value is not important, but the role of these filters is to eliminate high frequency noise after mixer 132. A different filter(s) may alternatively be employed in place of filters 134,136. The output of filter 136 is processed by two paths. The first path has a phase shifter 138 and a comparator 140. The second path has a comparator 142. The comparators convert the respective input signals to square waves. The outputs of the two comparators 140,142 are input to phase detector 144 which produces an output that is lowpass filtered with filter 146 having frequency response F₁₀. In the illustrated example, this has a cutoff frequency of 10 Hz.

A schematic of an example micromachined magnetic field sensor that can be employed as the electrostatic resonator with the above-described system and method is illustrated in FIG. 5. This includes a resonator and motion detector. More generally, any mechanical resonator can be used as long as it can be put in a configuration where the magnetic force from the magnetic field can be transferred and applied to the resonator body. The sensor is composed of an electrostatic resonator, beam springs, and two crossbars. The shuttle of the sensor is kept under mechanical resonance during the sensor operation. When inside a magnetic field B, the current ISB, which flows through the crossbars (from pin 1 to pin 2 and then pin 3 to pin 4), causes exertion of an axial force on the beam springs according to Lorentz force equation. The axial force modifies the stiffness of the flexural beams, and consequently, the resonant frequency of the structure changes. Although a comb-drive actuator is shown in the Figure, lateral or vertical parallel plate electrostatic resonators can also be employed as the main resonating body of the sensor. The operation of the sensor involves simultaneous interaction of multiple physical domains with each other, including electrostatics, magnetostatics, elasticity, dynamics, and electro-thermo-mechanics.

Magnetic fields are measured by this sensor not by means of any magnetic material, but by using Lorentz force. Therefore, this sensor does not suffer from non-linearity or hysterisis effects, especially for high magnetic field measurements.

Lorentz force is the force upon a moving electric current (electrons) in the presence of a magnetic field. This force is proportional to the multiplication of the magnitude of the electric current and the magnitude of the magnetic field. Thus, when electrons move in a magnetic field, Lorentz force tends to push or pull upon the electrons, and so upon the wire carrying the electrons.

Hall effect magnetic field sensors also use Lorentz force to displace moving electrons within a semi-conducting material, and so create a differential voltage. The sensor of FIG. 5, however, does not require semi-conducting materials, and simply requires the use of an electrically conducting material, which for example can be either a metal or semiconductor.

Since no magnetic or semi-conducting materials are needed for the construction of the sensor, it can be fabricated in standard commercial micromachining processes, without needing any special post processing fabrication steps. This sensor can be readily designed and/or fabricated by many companies in the MEMS industry, such as Micralyne, MEMSCAP, or Analog Devices. Consequently, the fabrication cost of this sensor will be low.

In the illustrated example, a mechanical vibrator is first fabricated on a substrate. This can be a micromachined vibrator, commonly referred to as a MEMS (micro-electro-mechanical system), in order to make a small sub-millimetre sized device that can be easily packed on a silicon chip. In the illustrated example, the vibrator is comprised of a “comb actuator”. However, any mechanical structure capable of being driven into oscillation at a controlled frequency can be used (bridge, cantilever, membrane, etc.). The supporting micromachined crossbars are anchored to the substrate such that an electric current can be passed through them. In the presence of a magnetic field the Lorentz force on the crossbars will push/pull on the beam springs themselves, thereby causing a mechanical load on the microsprings, which changes the spring constant of the micro-springs. This will result in a change in the resonant frequency of oscillations of the mechanical vibrator. This change in frequency is used as the magnetic field sense mechanism.

The sensor is operated at its mechanical resonant frequency. At this frequency, the amplitude of oscillation is significantly higher than normal. This increases the measurement sensitivity.

The magnetic field is measured by monitoring the change in the mechanical resonant frequency of the mechanical vibrator, due to the change in the spring constant of the micro-springs caused by the Lorentz force. The amount of frequency shift is proportional to the magnetic field. The direction of frequency shift (increase or decrease in resonant frequency) is dependant on the direction of the magnetic field and the current in the crossbars. This is different from most of the conventional sensors, which produce a voltage or a current signal at their output. Consequently, the output signal of the designed sensor is more robust against noise and interference.

The embodiments have been described in their application to sensing magnetic field strength. More generally, the closed loop embodiments can be used as resonators that do not require externally generated drive signals. For example, the described MEMS resonator in conjunction with the circuit described makes a arrangement that features a MEMS resonator that does not need an external frequency generation system. For example, the embodiments of FIGS. 1B and 3 provide can be used as such arrangements and may find applications other than sensing magnetic field strength. A specific example is a tuner circuit for a radio/cell phone. Instead of an external frequency generation system, spurious/environmental noise picked up by the circuit is filtered, and fed back to the mechanical resonator at the desired drive frequency. For such applications, there is no need for the output processing circuits of FIGS. 1B and 4 since no magnetic field is being measured. In some embodiments, the mechanical resonator is a MEMs resonator. Specific examples of MEMs resonators have been described above, but more generally, any MEMs resonator can be employed for such embodiments.

A specific example of a resonator arrangement that does not require an external drive signal has been described. In another embodiment, a MEMs resonator is provided together with a drive signal generation circuit that generates a drive signal for the MEMs resonator from an output of the MEMs resonator. The elements 32,34,36,38 of FIG. 1B provide one example of a drive signal generation circuit. Elements 102,104,106,108,110,112,114, 116,118,120,122,124,126 of FIG. 3 provide another example of a drive signal generation circuit.

Numerous modifications and variations of the present invention are possible in light of the above teachings. It is therefore to be understood that within the scope of the appended claims, the invention may be practiced otherwise than as specifically described herein.

1. An apparatus for measuring magnetic field comprising:
a mechanical resonator having a resonator output and having an input for receiving a drive signal;
signal conversion and amplification circuitry for converting the resonator output of the mechanical resonator into a voltage output representing a frequency of the resonator output; and
a sense signal filtering circuit to isolate a sense signal from an interfering feedthrough signal.

2. The apparatus of claim 1 wherein the sense signal filtering circuit comprises at least one of:
a notch filter having a notch at the expected resonant frequency divided by two;
one or more bandpass filters to isolate the sense signal from the interference signal; and
one or more additional high-Q bandpass filters to remove beating components.

3. The apparatus of claim 1 connected to form an oscillator loop with a feedback signal processing circuit that processes the sense signal to produce the drive signal;
wherein the sense signal has a frequency shift representative of a magnetic field within which the apparatus is situated.

4. An apparatus for measuring magnetic field comprising:
a mechanical resonator that undergoes mechanical motion and has an input for receiving a drive signal, the mechanical resonator having a resonant frequency that changes as a function of magnetic field;
a motion detector that detects the mechanical motion of the mechanical resonator; and
a sense signal filtering circuit for filtering a signal representative of the mechanical motion of the mechanical resonator to isolate a sense signal from interference due to the drive signal.

5. The apparatus of claim 4 further comprising:
signal conversion and amplification circuitry for converting an output of the motion detector into a voltage output as the signal representative of the mechanical motion of the mechanical resonator.

6. The apparatus of claim 4 wherein the sense signal filtering circuit comprises at least one of:
a notch filter having a notch at an expected resonant frequency divided by two;
one or more bandpass filters to isolate the sense signal from the interference due to the drive signal; and
one or more additional high-Q bandpass filters to remove beating components.

7. The apparatus of claim 4 further comprising:
a feedback signal processing circuit that processes the sense signal to produce the drive signal;
wherein the sense signal has a frequency shift representative of a magnetic field within which the apparatus is situated.

8. The apparatus of claim 7 wherein the feedback signal processing circuit comprises:
a constant amplitude circuit to make the sense signal have substantially constant amplitude;
a divide by 2 circuit;
a phase adjustment circuit.

9. The apparatus of claim 4 further comprising:
an output processing circuit that processes the sense signal to produce an output representative of the magnetic field within which the apparatus is situated.

10. The apparatus of claim 9 wherein the output processing circuit comprises:
a frequency dependent phase shifting circuit that produces a phase shifted output; and
a circuit that determines a phase shift introduced by the phase shifting circuit.

11. The apparatus of claim 10 wherein the circuit that determines a phase shift introduced by the phase shifting circuit comprises:
a phase detector.

12. The apparatus of claim 11 further comprising a phase difference to voltage converter, that produces a voltage that represents a value for the magnetic field.

13. The apparatus of claim 1 further comprising a downconverter circuit that downconverts a frequency of the sense signal.

14. The apparatus of claim 10 wherein the phase shifting circuit comprises an all pass filter.

15. The apparatus of claim 4 wherein the mechanical resonator comprises a resonant micromachined magnetic field sensor.

16. The apparatus of claim 4 wherein the mechanical resonator is driven by means of electrostatic, optical, thermal, piezoelectric, piezoresistive.

17. The apparatus of claim 4 wherein the motion detector comprises one of an electrostatic motion detector, optical motion detector, thermal motion detector, piezoelectric motion detector, and piezoresistive motion detector.

18. A method comprising:
placing a mechanical resonator having a resonator output and having an input for receiving a drive signal in an area for which a magnetic field measurement is to be determined;
converting and amplifying the resonator output into an electrical signal output representing a frequency of the resonator output; and
filtering the electrical signal output to isolate a sense signal from an interfering feedthrough signal.

19. The method of claim 18 further comprising:
feeding a version of the sense signal back as the drive signal to form a closed loop.

20. The method of claim 19 further comprising:
performing feedback signal processing upon the sense signal to produce the drive signal.

21. The method of claim 18 further comprising:
processing the sense signal to produce an output representative of the magnetic field.

22. A resonator arrangement comprising:
a mechanical resonator having a drive signal and a resonator output at the resonator output having a frequency that is twice a frequency of the drive signal;
a drive signal generation circuit that generates the drive signal for the mechanical resonator from the resonator output.

23. The resonator arrangement of claim 22 wherein the mechanical resonator is a MEMs resonator.

24. The resonator arrangement of claim 23 wherein the drive signal generation circuit comprises:
signal conversion and amplification circuitry for converting the resonator output of the mechanical resonator into a voltage output; and
a sense signal filtering circuit to isolate a sense signal from an interfering feedthrough signal.

25. The resonator arrangement of claim 24 wherein the sense signal filtering circuit comprises at least one of:
a notch filter having a notch at the expected resonant frequency divided by two;
one or more bandpass filters to isolate the sense signal from the interference signal; and
one or more additional high-Q bandpass filters to remove beating components.

26. The resonator arrangement of claim 23 wherein the drive signal generation circuit comprises:
a motion detector that detects the mechanical motion of the mechanical resonator; and
a sense signal filtering circuit for filtering a signal representative of the mechanical motion of the mechanical resonator to isolate a sense signal from interference due to the drive signal.

27. The resonator arrangement of claim 26 further comprising:
signal conversion and amplification circuitry for converting an output of the motion detector into a voltage output as the signal representative of the mechanical motion of the mechanical resonator.

28. The resonator arrangement of claim 26 wherein the apparatus drive signal generation circuit further comprises:
a feedback signal processing circuit that processes the sense signal to produce the drive signal.

29. The resonator arrangement of claim 28 wherein the feedback signal processing circuit comprises:
a constant amplitude circuit to make the sense signal have substantially constant amplitude;
a divide by 2 circuit;
a phase adjustment circuit.

30. The apparatus of claim 1 wherein the resonator output has a frequency that is twice a frequency of the drive signal.

31. The apparatus of claim 4 wherein the resonator output has a frequency that is twice a frequency of the drive signal.

32. The method of claim 18 wherein the resonator output has a frequency that is twice a frequency of the drive signal.
